(19) United States
(12) Patent Application Publication
(10) Pub. No.: US 2007/0218649 A1
(43) Pub. Date: Sep. 20, 2007

(54) SEMICONDUCTOR WAFER THINNING

(75) Inventor: Caroline Hernandez, Peyrolles (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMicroelectronics SA, Montrouge (FR)

(21) Appl. No.: 11/748,995

(22) Filed: May 15, 2007

Related U.S. Application Data
(63) Continuation of application No. PCT/FR05/50959, filed on Nov. 17, 2005.

(30) Foreign Application Priority Data
Nov. 17, 2004 (FR) 04/52661

(51) Int. Cl. H01L 21/461; H01L 21/46

(52) U.S. Cl. 438/458; 438/459; 438/977; 257/618

(57) ABSTRACT

A method for processing a first semiconductor wafer having a first surface and a second surface, by placing, on the second surface of the first wafer, a second wafer with an interposed resist layer, and thinning down the first surface of the first semiconductor wafer.

### BACKGROUND OF THE INVENTION

1. Technical Field

The present invention relates to the field of microelectronics and, more specifically, to the thinning of a wafer made of a semiconductor material in which electronic circuits have been manufactured or which is intended to be used to manufacture such circuits.

2. Description of the Related Art

Thinning down integrated circuits or wafers of a semiconductor material supporting such circuits is a constant need of the microelectronics industry. Such a thinning down to thicknesses of a few tens of micrometers or even a few micrometers provides many possibilities in terms of applications for the electronic circuits thus formed. Thin integrated circuit chips are likely to be used in many electronic applications, be it independently or for assembly to other chips or substrates.

Among such applications, the integration of electromagnetic transponders to form very thin electronic tags likely to be supported by banknotes, clothes, wrappings, etc. will be mentioned as an example.

Another example of application is the forming of solar cells.

Another example of application relates to the insertion of integrated circuits in flexible or rigid supports for applications of electronic passport, smart card and the like type.

Another example of application relates to the forming of optical micropackages in which a very thin integrated circuit is transferred on a glass slab.

However, the thinning of semiconductor wafers poses several problems.

A first problem is that, if a wafer is thinned down before manufacturing of the components and circuits, it becomes difficult to handle for subsequent processings due to its fragility.

This constraint results in that the wafers are generally thinned down at the end of the manufacturing by being glued on adhesive tapes enabling handling thereof. For example, a wafer of a thickness of a few hundreds of micrometers on a front surface of which integrated circuits have been formed is glued by this front surface (possibly with an interposed protection layer) on an adhesive tape used as a handling support. The wafer is then thinned down from its rear surface, for example, by rectification (grinding), by chemical etch or dry etch (plasma). Once the wafer has reached the desired final thickness (for example, a few tens of micrometers), the integrated circuit chips are generally cut while they are still glued on the adhesive tape, then are taken one by one from this adhesive tape, for example, for integration in a smart card.

The use of adhesive tapes has several disadvantages.

Even if the adhesive tape is more or less rigid, it is made of a material of a nature different from that of the wafer, which generates, among others, differences in the mechanical stress.

Further, the separation of an adhesive tape is generally performed by tearing, generating risks of damaging the integrated circuits supported by the semiconductor wafer.

Further, the adhesive used to stick the tape on the semiconductor wafer risks generating contaminations in the active wafer areas and certain processings are not compatible with the use of an adhesive tape, due to risks of pollution by degassing of these components.

Further, possible surface unevennesses of the semiconductor wafer may generate a rupture of the wafer due to the mechanical stress in the thinning (especially in case of a grinding rectification).

U.S. Patent Application Publication No. 2004/0121618 describes the forming of a glue usable to temporarily attach a semiconductor wafer to a rigid substrate in the wafer thinning. The use of such a glue of complex composition is likely to pose problems of contamination of the active areas of the circuits supported by the semiconductor wafer. Further, its application and the subsequent gluing and separation steps require a dedicated equipment.

U.S. Pat. No. 6,013,534 describes a method for thinning integrated circuit chips after cutting by using an etch stop layer as well as a wax layer. Such a method substantially exhibits the same disadvantages as the use of an adhesive tape and further requires a high-temperature anneal due to the use of a wax. Such anneals are noxious for the components formed in the wafer, especially transistors, by creating stress likely to cause breakages or to generate dopant diffusions resulting in malfunctions.

### BRIEF SUMMARY

Various embodiments described herein overcome all or part of the disadvantages of known techniques for thinning down a wafer made of a semiconductor material.

In particular, the embodiments ease the implementation of such a thinning by using techniques compatible with those used for the manufacturing of electronic circuits on the wafer.

In one embodiment, the present invention provides a method applicable to a semiconductor wafer before as well as after manufacturing of components (especially, before the forming of areas specifically doped by implantation/diffusion).

In certain embodiments, the present invention also avoids any risk of stress or contamination of the components formed in the semiconductor wafer.

In a further embodiment, the present invention provides a method compatible with the use of equipment currently used to handle and process semiconductor wafers.

One embodiment of the present invention provides a method for thinning down a first semiconductor wafer from a first surface, consisting of placing, on the second surface of the first wafer, a second wafer with an interposed resist layer.

According to an embodiment of the present invention, the resist layer is removed by means of a solvent, after thinning of the first wafer to separate the second wafer.

According to an embodiment of the present invention, the resist layer is etched, preferably, according to a regular pattern over the entire first wafer.

According to an embodiment of the present invention, the etch pattern of the resin is obtained by means of a mask having been used to define electronic component manufacturing patterns.

According to an embodiment of the present invention, the first and second wafers are made of the same semiconductor material.

According to an embodiment of the present invention, the method is applied to a first wafer in which electronic components have been formed.

According to an embodiment of the present invention, the method is applied to a first wafer before forming of electronic components.

According to an embodiment of the present invention, the first wafer supports solar cells.

According to an embodiment of the present invention, the first wafer is intended to be placed on a glass plate for an optical application.

According to an embodiment of the present invention, the separation of the first wafer is performed after cutting of integrated circuit chips.

According to an embodiment of the present invention, the first wafer after thinning exhibits a thickness smaller than 5 micrometers.

The present invention also provides an assembly formed of a first semiconductor wafer, of a second semiconductor wafer relatively thick with respect to the first one, and of a resist layer between the two wafers.

According to an embodiment of the present invention, said thin wafer exhibits a thickness smaller than 50 micrometers.

According to an embodiment of the present invention, the wafers are made of a same semiconductor material.

The present invention also provides an integrated circuit or discrete component chip.

The foregoing and other features, and advantages of the present invention will be discussed in detail in the following non-limiting description of specific embodiments in connection with the accompanying drawings.

### BRIEF DESCRIPTION OF THE SEVERAL VIEWS OF THE DRAWINGS

FIGS. 1A, 1B, 1C, 1D, 1E, and 1F illustrate, in very simplified cross-section views, an embodiment of the present invention;

FIGS. 2A and 2B very schematically illustrate in cross-section views a first variation of the present invention;

FIGS. 3A and 3B very schematically illustrate in cross-section views a second variation of the present invention;

FIGS. 4A and 4B very schematically illustrate in cross-section views a third variation of the present invention;

FIG. 5 very schematically illustrates in cross-section view a fourth variation of the present invention;

FIG. 6 very schematically illustrates in cross-section view a fifth variation of the present invention;

FIGS. 7A and 7B very schematically illustrate in cross-section views an example of application of the present invention to the forming of solar cells; and

FIGS. 8A, 8B, and 8C very schematically illustrate in cross-section views another example of application of the present invention to the forming of vertical circuits.

### DETAILED DESCRIPTION

The same elements have been designated the same reference numerals in the different drawings which have been drawn out of scale. For clarity, only those steps and elements which are necessary to the understanding of the present invention have been shown in the drawings and will be described hereafter. In particular, the steps of integrated circuit manufacturing on the semiconductor wafer have not been detailed, the present invention being compatible with any conventional electronic circuit manufacturing method. Similarly, the actual thinning of a semiconductor wafer supported by a substrate according to the present invention has not been detailed, the present invention being here again compatible with all conventional thinning techniques.

According to a preferred embodiment of the present invention, a first semiconductor wafer to be thinned down from a first surface is placed by its first surface on a substrate formed of a second wafer, preferably of same nature, with an interposed resist layer. The resist is used as a layer of protection and of temporary hold of the two wafers together, at least until the end of the thinning of the first wafer.

The resist used to temporarily stick the two wafers is any resist (positive or negative) currently used in microelectronics, in particular, to define implantation, deposition, or etch masks. Against all expectations, such resins have a sufficient adhesive power to stand the mechanical stress linked to a thinning of the rear surface (including by grinding rectification) and may be easily separated at the end of the thinning. Such a separation is performed by means of a solvent of the type currently used to remove such resin layers during manufacturing of integrated circuits.

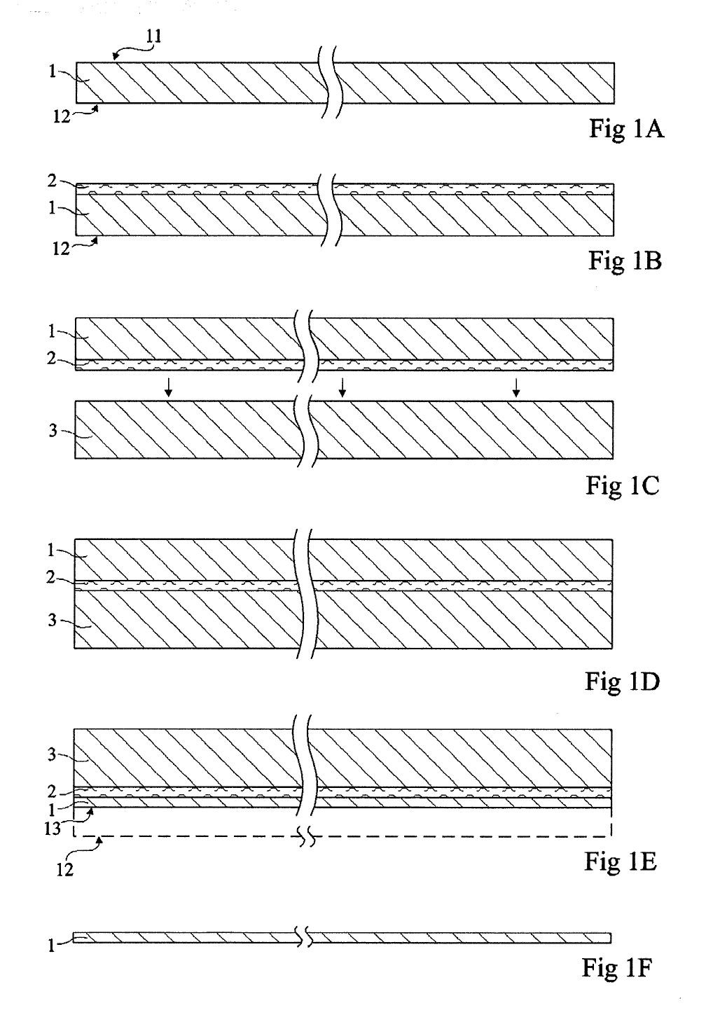

FIGS. 1A to 1F illustrate, in very simplified cross-section views, an embodiment of the thinning method according to the present invention.

A semiconductor wafer 1 (for example, silicon) intended to be thinned down (FIG. 1A) from a first surface 12 (said to be rear) is covered on a second surface 11 (said to be the front surface) with a resist layer 2 (FIG. 1B). For example, and conventionally for the deposition of such a resin, it is deposited in viscous form on wafer 1 by a so-called spin deposition technique.

In the case (FIGS. 1A and 1B) where wafer 1 has no pattern, the thickness of layer 2 is not critical and ranges, for example, between 50 nm and 5 μm.

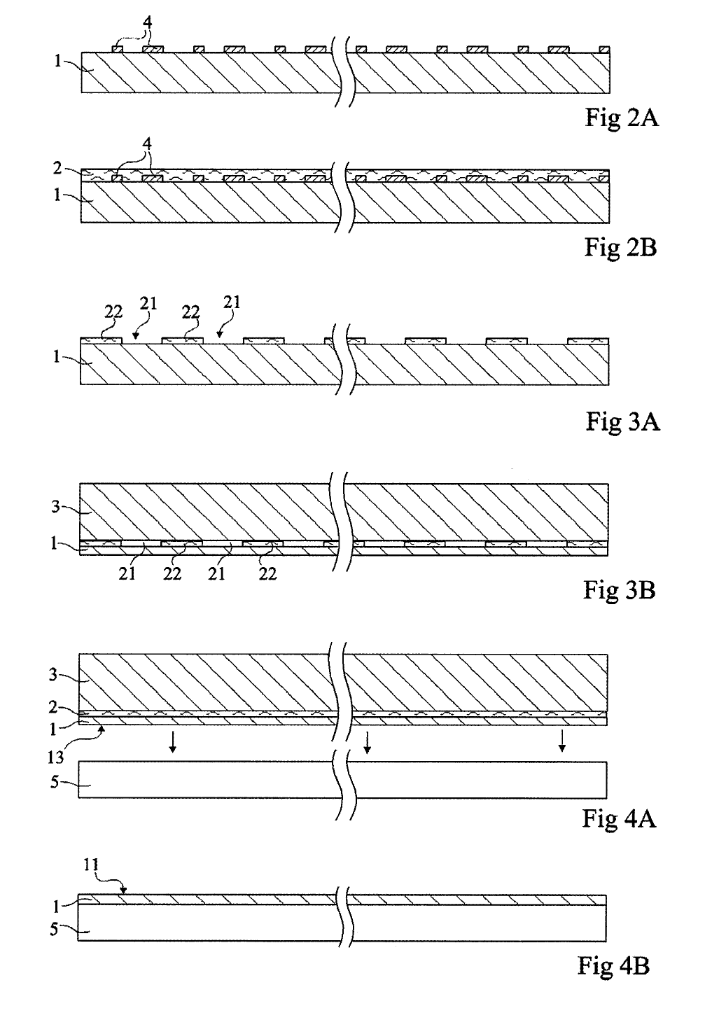

According to a first variation illustrated in FIGS. 2A and 2B, which are to be compared with FIGS. 1A and 1B, front surface 11 comprises protruding patterns 4 (for example, steps, chips, metallizations, etc.). The thickness of resin layer 2 is then selected to uniformly fill these patterns.

As a specific example of embodiment, resists known under trade names SPR955, THMR2250, APEX2408, or M78Y may be used.

A second wafer 3, intended to be used as a support (handle) for subsequent handlings of the assembly, is placed on resin layer 2 (FIG. 1C). Preferably, wafer 3 is made of the same material as wafer 1. For example, it may be defective wafers intended to be destroyed or thrown away. The thickness of wafer 3 is, for example, several hundreds of micrometers.

The adherence of the two wafers may be enhanced by cleaning support wafer 3 by means of a solvent selected from among those currently used to ease the spreading of a resist on a semiconductor wafer (for example, a solvent based on acetic acid and 2-methoxy-1-methylethylester, known under trade name “EC solvent”).

According to an embodiment, no anneal of resin 2 is performed and only a drying at ambient temperature is performed. Such a drying is enough to provide the resin with a sufficient stiffness for the subsequent thinning processings.

According to another embodiment, the drying is accelerated by an anneal at low temperature, that is, at a temperature lower than the melting temperature of resin 2 (for example, lower than 150 degrees).

The assembly (FIG. 1D) is transferred to a station (not shown) of thinning down of wafer 1 from its first surface 12.

The thinning (FIG. 1E) is carried on to obtain the final thickness desired for wafer 1. For example, starting from a thickness of a few hundreds of micrometers (for example, 300 or 600 μm) for wafer 1, it is thinned down to a thickness of a few tens of micrometers, or even a few micrometers (for example, less than 5 μm).

An assembly formed of a first wafer 1 (typically, less than 50 μm) relatively thin with respect to a second relatively thick wafer 3 (several hundreds of micrometers) used as a support, between which is present a resist layer 2 for temporarily holding the wafers together, is then obtained.

Finally, according to this embodiment (FIG. 1F), the two wafers are separated from each other (unstuck) by plunging the assembly in a solvent bath to dissolve resin 2.

The solvent used can be any solvent conventionally used to dissolve a resist. For example, an acetone-based solvent (for example, pure acetone), a sodium hydroxide and sulfuric acid-based solution, or more specific solvents such as a solvent based on acetic acid and 2-methoxy-1-methylethylester, or based on methylethylketone and ethyl lactate, known under trade name “RER”, etc., may be used.

FIGS. 3A and 3B show a second variation of FIGS. 1B (or 2B) and 1E according to a preferred embodiment of the present invention. Resin layer 2 is etched (FIG. 3A) to exhibit empty areas 21 or channels to ease the subsequent separation of the two wafers 1 and 3 by flowing of the solvent within layer 2. The use of a resist enables such an implementation, be it a positive or negative resist. According to this embodiment, after spreading of resin 2, a low-temperature anneal is performed to stiffen it before performing a photolithographic etch (photograph+development). Second wafer 3 is then placed on the resin layer to which it adheres by resin pads 22 which remain.

For the case where the anneal prior to the sticking of wafers 1 and 3 reduces the resin adherence, a sufficient adhesion capacity can be recovered by cleaning support wafer 3 by means of a solvent selected from among those currently used to enhance the spreading of a resist, for example above-mentioned “EC-solvent” or “RER” solvents.

Of course, the solvent concentrations and/or the application times of these solvents are adapted on the one hand to the development of the photolithographic etch and on the other hand to the desired separation of the wafers at the end of the thinning.

According to an embodiment, a specific mask is formed to guarantee a regular pattern (preferably, tablecloth) over the entire wafer. As regular a pattern as possible will preferably be employed to avoid introducing risks of mechanical stress by bearing differences in the wafer surface.

Most often, the obtaining of such regular patterns is compatible with the use of one of the available masks, used for the component manufacturing in the wafer. An advantage then is that the present invention reuses, to define channels of acceleration of the wafer separation, any mask used for the component manufacturing.

FIGS. 4A and 4B illustrate a third embodiment of the present invention according to which thinned wafer 1 must be definitively supported by another support (for example, a glass plate 5 or an oxidized silicon substrate). Rear surface 13 of thinned wafer 1 is placed (FIG. 4A) on support 5, preferably, before being separated (FIG. 4B) from wafer 3.

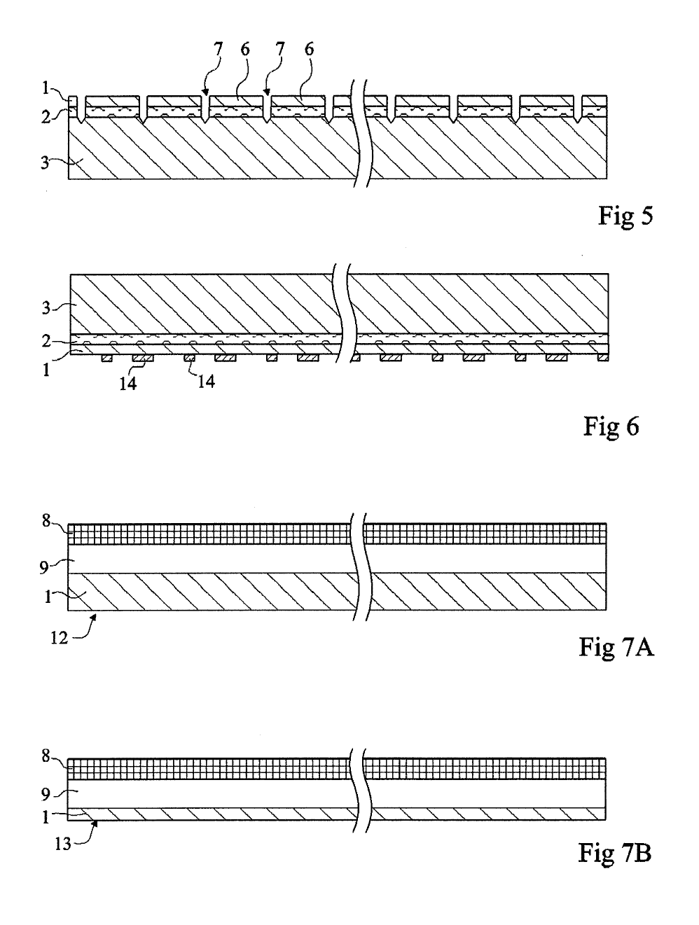

According to a fourth alternative embodiment illustrated in FIG. 5, the separation is performed after cutting of integrated circuit chips 6 in the thinned wafer, cutting lines 7 stopping, for example, in support wafer 3.

FIG. 6 illustrates a fifth variation of the present invention according to which other processings are performed, from rear surface 13 of thinned wafer 1, before separation. For example, a rear surface metallization (possibly with patterns 14) or any other processing may be performed, provided that the processing temperature remains under the melting temperature of resin 2. This constraint is compatible with the development of low-temperature manufacturing methods.

FIGS. 7A and 7B illustrate an example of application of the present invention to the forming of solar cells 8 on germanium substrates 9 supported by silicon substrates 1 which are desired to be thinned down to lighten the structure.

In FIG. 7A, the wafer in which the solar cells have been formed, for example, by resuming a hetero-epitaxy of material of columns III-V of the periodical classification of elements have been shown.

The method illustrated in FIGS. 1A to 1F is implemented from the free surface of wafer 1 to obtain a thinned wafer (FIG. 7B) supporting substrate 9 and cells 8.

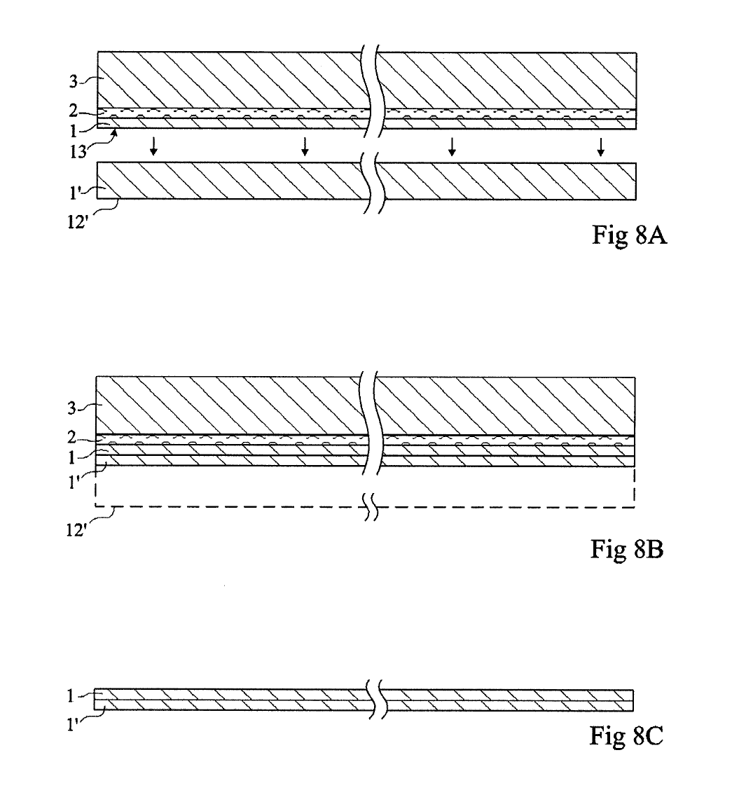

FIGS. 8A to 8C illustrate a second example of application of the present invention to the forming of stackings of circuits supported by successive wafers. In this example of application, the structure resulting from FIG. 1E is glued (FIG. 8A) on a third silicon wafer 1′ and the assembly is submitted to a new thinning (FIG. 8B) from rear surface 12′ of wafer 1′. A stacked structure of thin wafers is obtained (FIG. 8C).

An advantage of the present invention is that the use of a resist currently used to define patterns on the semiconductor wafer does not risk generating an unusual contamination of the active areas that may be formed in this wafer.

Another advantage of the present invention is that by using a substrate made of a semiconductor substrate of same nature as the wafer to be thinned down, the possible problems linked to expansion coefficient differences are avoided.

Another advantage of the present invention is that the assembly of the wafer to be thinned and of the support wafer is compatible with all equipments currently used to process semiconductor wafers, and may be seen by such equipments as a single wafer. This advantage is particularly significant in the case where the wafer is thinned down from a first surface before manufacturing and remains attached to the support wafer for the implementation of manufacturing steps from the free surface of the thinned down surface.

Another advantage of the present invention is that the resist has the double function of protecting the patterns manufactured on the semiconductor wafer and of a layer of adhesion to the support wafer.

Another advantage of the present invention is that the thinning down can be performed at any step of the manufacturing. For example, the thinning down may be performed on the raw wafer, after forming of the active areas, after forming of the chips, or after forming of the interconnect metallization levels.

Another advantage of the present invention, in the case where wafer 1 is separated before cutting, is that support wafer 3 is reusable as a support for other wafers, subsequently.

Of course, the present invention is likely to have various, alterations, improvements, and modifications which will readily occur to those skilled in the art. In particular, although the present invention has been described in relation with a silicon wafer example, it is compatible with whatever the semiconductor material forming the wafer to be processed (for example, SiGe, AsGa, etc.).

Further, the practical implementation of the present invention based on the functional indications given hereabove is within the abilities of those skilled in the art and the different variations may be combined.

Moreover, although reference has sometimes been made to an integrated circuit, the present invention applies to any electronic circuit formed in a semiconductor wafer, be it actual integrated circuits or discrete component chips (such as power components).

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary, to employ systems, circuits and concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for thinning down a first wafer having a first surface and a second surface, comprising:
placing a resist layer on the second surface;
etching the resist layer according to a regular pattern to form an etched resist layer;
placing a second wafer on the etched resist layer; and
thinning down at the first surface of the first wafer.

2. The method of claim 1 further comprising, after thinning of the first wafer, separating the second wafer from the first wafer.

3. The method of claim 2, wherein the second wafer is separated from the first wafer by removing the resist layer using a solvent.

4. The method of claim 1, wherein the regular pattern for etching the resist layer is provided by a mask having been used to define electronic component manufacturing patterns.

5. The method of claim 1, wherein the first wafer and the second wafer are made of the same semiconductor material.

6. The method of claim 1, wherein the method is applied to the first wafer in which electronic components have been formed.

7. The method of claim 6, wherein the first wafer is thinned down before forming of electronic components.

8. The method of claim 1, wherein the first wafer supports solar cells.

9. The method of claim 1, wherein the first wafer is placed on a glass plate for an optical application.

10. The method of claim 1, wherein the separation of the first wafer is performed after cutting of integrated circuit chips.

11. The method of claim 1, wherein the first wafer after thinning exhibits a thickness smaller than 5 micrometers.

12. An assembly comprising:
a first semiconductor wafer;
a second semiconductor wafer relatively thicker with respect to the first semiconductor wafer; and
a resist layer between the first and second semiconductor wafers.

13. The assembly of claim 12, wherein said first semiconductor wafer exhibits a thickness smaller than 50 micrometers.

14. The assembly of claim 12, wherein the first and second semiconductor wafers are made of a same semiconductor material.

15. An integrated circuit obtained by a method comprising:
providing a first wafer having a first surface and a second surface;
placing, on the second surface of the first wafer, a second wafer and an interposed resist layer; and
thinning down at the first surface of the first wafer to provide a thinned first wafer.

16. The integrated circuit of claim 15 wherein the method further comprising separating the thinned first wafer from the second wafer.

17. The integrated circuit of claim 15 wherein the method further comprising forming an electrical component on the thinned first wafer.

18. The integrated circuit of claim 15 wherein the method further comprising forming an electrical component on the first wafer prior to thinning down at the first surface of the first wafer.

19. A method of thinning a semiconductor wafer having a first surface and a second surface, comprising:
placing a resist layer on the second surface;
attaching a support wafer to the resist layer; and
thinning down the semiconductor wafer at the first surface thereof.

20. The method of claim 19 further comprising separating the semiconductor wafer from the support wafer by dissolving the resist layer.

21. The method of claim 19 wherein the resist layer is etched to provide a plurality of channels before attaching the support wafer.

22. The method of claim 19 wherein the support wafer is thicker than the semiconductor wafer.

23. The method of claim 19 further comprising, after the step of thinning:
forming an electronic component on the semiconductor wafer.

24. The method of claim 19 further comprising, prior to the step of thinning:
forming an electronic component on the semiconductor wafer.
